(19) United States
(12) Patent Application Publication
(10) Pub. No.: US 2026/0118416 A1
(43) Pub. Date: Apr. 30, 2026

(54) CHUCK

(71) Applicant: VUETTE PTE. LTD., Singapore (SG)

(72) Inventors: Choon Leong LOU, Singapore (SG); Ho Yeh CHEN, Hsinchu County (TW); Ban Ban LIM, Singapore (SG)

(21) Appl. No.: 19/084,687

(22) Filed: Mar. 19, 2025

(30) Foreign Application Priority Data
Oct. 29, 2024 (CN) 202411520084.1

(51) Int. Cl. G01R 31/28

(52) U.S. Cl. CPC G01R 31/2891; G01R 31/2831

(57) ABSTRACT

A chuck, which includes a support plate, a support shaft, and a thermal insulation member. The support plate is used to hold a wafer. The support shaft is disposed below the support plate for supporting the support plate. The thermal insulation is disposed between the support plate and the support shaft.

### CROSS-REFERENCE TO RELATED PATENT APPLICATION

This application claims the benefit of priority to China Patent Application No. 202411520084.1, filed on Oct. 29, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chuck, and more particularly to a chuck including a thermal insulation member.

### BACKGROUND OF THE DISCLOSURE

Wafer testing is often required in the semiconductor manufacturing process to promptly identify and pick out defective wafers. Wafer testing is performed using contact pins connected to a probe card providing an interface between the test system and the wafer, which is supported below the probe card and heated to an appropriate test temperature. Wafer testing is typically performed at temperatures ranging between −60° C. and 300° C., and even at more extreme temperatures. In the case of high-temperature testing, wafers are often heated during the testing process. However, the high temperature transmitted to the support shaft of the wafer carrier unit may cause the support shaft to thermally expand, affecting the alignment operation of the support shaft. Therefore, it is necessary to avoid high-temperature transmission to the support shaft.

In the existing technology, cooling pipes or screw cooling methods are usually used to cool the wafer carrier unit with the coolant. However, the coolant is susceptible to environmental influences that make it difficult to maintain at low temperatures, and less stable, resulting in poor cooling effect. In addition, the cost of coolant is higher.

### SUMMARY OF THE DISCLOSURE

In response to the above-referenced technical inadequacies, the present disclosure provides a chuck.

In order to solve the above-mentioned problems, one of the technical aspects adopted by the present disclosure is to provide a chuck, which includes a support plate for holding a test wafer; a support shaft disposed below the support plate and for supporting the support plate; and a thermal insulation member disposed between the support plate and the support shaft. The thermal insulation member further includes at least one first thermal insulation member, at least one second thermal insulation member, and at least one cavity. At least one fluid channel is provided in the cavity, and the cavity is surrounded by the first thermal insulation member and the second thermal insulation member. The first thermal insulation member is disposed above the second thermal insulation member and adjacent to the support plate. A thermal conductivity of the first thermal insulation member is greater than a thermal conductivity of the second thermal insulation member. At least one thermal insulation region is provided in the thermal insulation member, and the at least one thermal insulation region is arranged between the support plate and the support shaft.

In one of the possible or preferred embodiments, the thermal insulation member further has at least one fluid inlet spatially communicated with the cavity to direct a cooling fluid into the cavity and at least one fluid outlet spatially communicated with the cavity to direct the cooling fluid out of the cavity.

In one of the possible or preferred embodiments, the fluid inlet and the fluid outlet are at the same level.

In one of the possible or preferred embodiments, the first thermal insulation member includes a plurality of fins.

In order to solve the above-mentioned problems, another one of the technical aspects adopted by the present disclosure is to provide a chuck, which includes a support plate for holding a test wafer; a support shaft disposed below the support plate and for supporting the support plate; and a thermal insulation member disposed between the support plate and the support shaft. The thermal insulation member further includes a first thermal insulation member, a second thermal insulation member, and at least one cavity. A thermal conductivity of the first thermal insulation member is equal to a thermal conductivity of the second thermal insulation member. At least one fluid channel is provided in the cavity, and the cavity is surrounded by the first thermal insulation member and the second thermal insulation member. At least one thermal insulation region is provided in the thermal insulation member, and the at least one thermal insulation region is arranged between the support plate and the support shaft.

In one of the possible or preferred embodiments, the thermal insulation member further has at least one fluid inlet spatially communicated with the cavity to direct a cooling fluid into the cavity and at least one fluid outlet spatially communicated with the cavity to direct the cooling fluid out of the cavity. The fluid inlet is arranged below the fluid outlet.

In one of the possible or preferred embodiments, a width of the thermal insulation member is greater than or equal to a width of the support shaft.

In one of the possible or preferred embodiments, the thermal insulation member includes a plurality of fins.

In one of the possible or preferred embodiments, the first thermal insulation member and the second thermal insulation member are made of the same material.

In one of the possible or preferred embodiments, the first thermal insulation member and the second thermal insulation member are integrally formed.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1a is a schematic side view of a chuck according to a first embodiment of the present disclosure;

FIG. 1b is a schematic side view of the chuck of a variation according to the first embodiment of the present disclosure;

FIG. 2a is a schematic side view of the chuck according to a second embodiment of the present disclosure;

FIG. 2b is a schematic side view of the chuck of a variation according to the second embodiment of the present disclosure;

FIG. 3 is a schematic side view of the chuck according to a third embodiment of the present disclosure;

FIG. 4 is a schematic perspective view of the chuck according to a fourth embodiment of the present disclosure;

FIG. 5 is a schematic side view of the chuck according to the fourth embodiment of the present disclosure; and

FIG. 6 is a schematic side view of a wafer test device according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

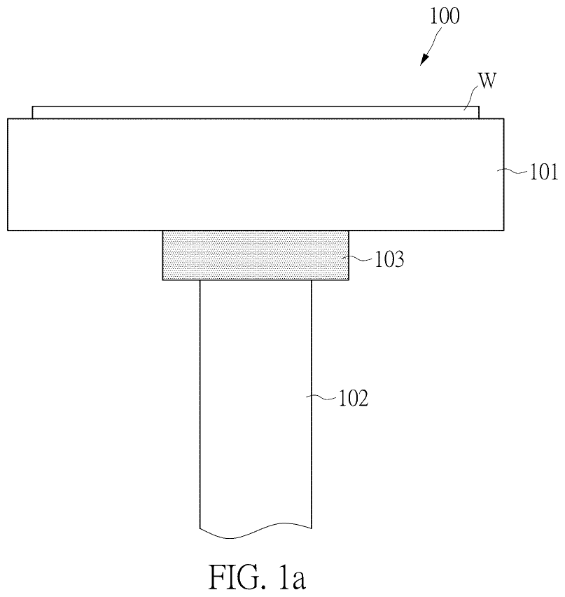

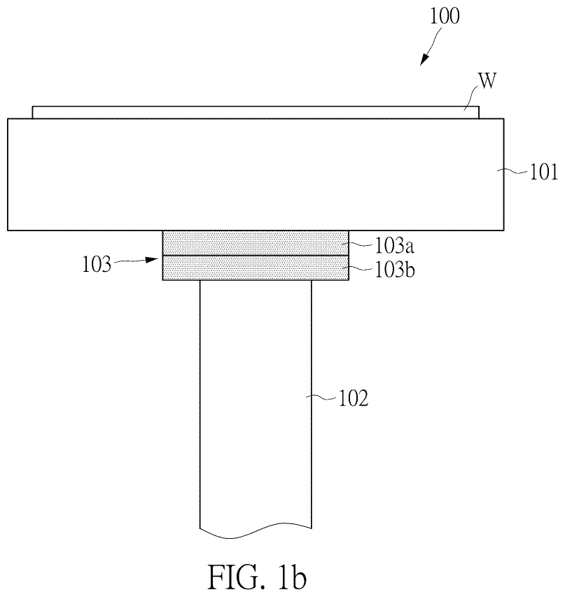

Reference is made to FIG. 1a, in which a schematic side view of a chuck according to a first embodiment of the present disclosure is shown. A chuck 100 can include a support plate 101, a support shaft 102, and a thermal insulation member 103. The support plate 101 is used to carry a wafer W to be processed, and the support shaft 102 is disposed below the support plate 101 and used to support the support plate 101. In one embodiment, the support shaft 102 can include a vertical drive portion and a horizontal drive portion to move the support plate 101 respectively in a vertical direction and a horizontal direction, so that alignment of a probe card and the wafer W can be performed. Optionally, a width of the thermal insulation member 103 is greater than or equal to a width of the support shaft 102, so that the insulation member 103 can be securely disposed between the support plate 101 and the support shaft 102.

Further, a thermoregulation unit can be provided in the support plate 101 for heating or cooling the wafer W, whereby temperature of the wafer W can be regulated through a heater or a cooler of the thermoregulation unit. However, the thermal insulation member 103 can be disposed between the support plate 101 and the support shaft 102 in order to avoid the heat applied to the wafer W from being transmitted to the support shaft 102. The support plate 101 and the support shaft 102 can be partially spaced apart from each other by the thermal insulation member 103. Preferably, the support plate 101 and the support shaft 102 are spaced apart from each other by the thermal insulation member 103, i.e., the support plate 101 is not in contact with the support shaft 102.

Accordingly, as shown in the schematic side view of FIG. 1, the width of the thermal insulation member 103 can be greater than the width of the support shaft 102. In addition, a ratio of the width of the thermal insulation member 103 to the width of the support shaft 102 can be 1:1 to 1:2, such that an effect of spacing the support plate 101 from the support shaft 102 can be achieved without substantially causing an increase of manufacturing cost of the thermal insulation member 103.

In another embodiment, a surface area of a top surface of the thermal insulation member 103 is equal to a surface area of a bottom surface of the support plate 101 that is in contact with the thermal insulation member 103. In other words, the top surface of the thermal insulation member 103 fits snugly against the bottom surface of the support plate 101. That is, no through hole is provided on a contact surface between the thermal insulation member 103 and the support plate 101.

In order that the thermal insulation member 103 can prevent heat of the support plate 101 from being transmitted to the support shaft 102 without taking away the heat applied to the wafer W, the thermal insulation member 103 can be made of a highly thermally conductive material having a thermal conductivity (coefficient of thermal conductivity) of greater than 10 W/m·K, for example, a thermal conductivity of 34 W/m·K, 35 W/m·K, 60 W/m·K, 70 W/m·K, 80 W/m·K, 237 W/m·K, 401 W/m·K, etc. For example, the thermal insulation member 103 can be made of ceramic, iron, copper, etc., which is highly thermally conductive. However, the above examples are merely one of the possible embodiments and are not intended to limit the present disclosure. In one embodiment, the thermal insulation member 103 can have the thermal conductivity greater than 10 W/m·K and less than 420 W/m·K. In another aspect, the thermal insulation member 103 can be made of a thermal insulation material having a thermal conductivity (coefficient of thermal conductivity) of less than 2 W/m·K, such as glass (having a thermal conductivity of 1.4 W/m·K) and low thermally conductive ceramic (having a thermal conductivity of less than 2 W/m·K), but the present disclosure is not limited thereto.

In one embodiment, the thermal insulation member 3 has at least one cavity S, and at least one thermal insulation region is provided in the at least one cavity S. Specifically, the thermal insulation member 3 can have a plurality of holes that can be used in conjunction with air (having a thermal conductivity of 0.026 W/m·K) for heat insulation. Further, the cavity S can be used to receive a cooling fluid to pass through. Specifically, the cavity S can directly serve as a conduction channel, or can serve as a conduit (not shown in the figures) passing through the thermal insulation member 103. Accordingly, a gas or a liquid for cooling can flow in the thermal insulation member 103 via the conduit, so as to remove the heat transmitted to the thermal insulation member 103 from the thermal insulation member 103, thereby increasing heat dissipation efficiency of the thermal insulation member 103. When viewed from a side of a cross-section, the gas or the liquid for cooling flow in different directions in two adjacent conduits. In another embodiment of the present disclosure, the thermal insulation member 103 can be a thermoelectric cooler (Peltier cooler).

According to the above, the thermal insulation member 103 of the present disclosure can be a configuration that individually has a heat conduction effect or individually has a heat insulation effect, or a configuration that has both heat conduction and heat insulation effects. Specifically, the heat conduction effect is applied to conduct the heat that is transmitted from the support plate 101 to the support shaft 102 to the thermal insulation member 103, and can cooperate with liquid cooling, air cooling, etc., to remove the heat, but not substantially to remove the heat from the support plate 101, so that the impact on heating efficiency to the wafer W can be minimized. The heat insulation effect is achieved in a manner that the heat is insulated by the thermal insulation member 103, so that the heat is not/is not readily conducted to the support shaft 102.

Referring to FIG. 1b, in another aspect, the thermal insulation member 103 can at least include a first thermal insulation member 103a adjacent to the support plate 101 and a second thermal insulation member 103b adjacent to the support shaft 102. In other words, the first thermal insulation member 103a is arranged above the second thermal insulation member 103b, and at least one cavity S is provided as the thermal insulation region. Optionally, the first thermal insulation member 103a and the second thermal insulation member 103b can be made of different materials. For example, a thermal conductivity of the first thermal insulation member 103a can be greater than a thermal conductivity of the second thermal insulation member 103b, such that the heat from the support plate 101 is readily removed by the thermal insulation member 103 while not being readily conducted to the support shaft 102.

### Second Embodiment

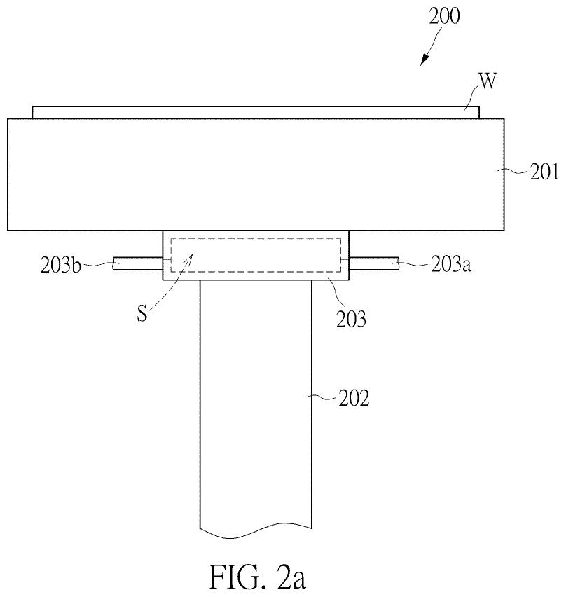

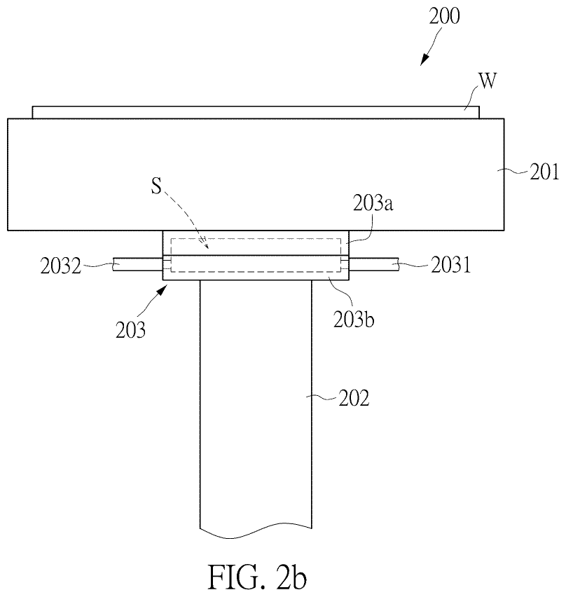

Reference is made to FIG. 2a, in which a schematic side view of a chuck 200 according to a second embodiment of the present disclosure is shown, in another embodiment of the present disclosure, the chuck 200 can include a support plate 201, a support shaft 202, and a thermal insulation member 203. The similarities between the second embodiment and the first embodiment will not be reiterated herein. In the present embodiment, the thermal insulation member 203 can have a cavity S for receiving clean dry air (CDA) or a coolant. In addition, the thermal insulation member 203 further has a fluid inlet 2031 and a fluid outlet 2032 to direct the CDA or the coolant respectively into and out of the cavity S, thereby facilitating the flow of the CDA or the coolant. In one embodiment of the present disclosure, the fluid inlet 2031 and the fluid outlet 2032 are at the same level. In addition, a pipe material of each of the fluid inlet 2031 and the fluid outlet 2032 can be a metal material, such as iron and an alloy, to achieve a better cooling effect. Further, a flow rate of the CDA or the coolant can be determined based on a detected temperature of the wafer W. In the present disclosure, the flow rate refers to a volume of gas flowing per unit time.

Specifically, the cavity S can be directly used as a flow space for the CDA or the coolant, or a fluid channel can be provided in the cavity S to allow the CDA or the coolant to flow therein. When the CDA or the coolant is introduced into the cavity S with a first temperature, the CDA or the coolant is discharged from the cavity S with a second temperature, and the second temperature is greater than the first temperature, indicating that the CDA or the coolant is effective in taking the heat from the cavity S. For example, the CDA can be oxygen, nitrogen, argon, hydrogen, etc. The coolant can be deionized water, silicon oil, and other liquids with a cooling effect. However, the above examples are merely one of the possible embodiments and are not intended to limit the present disclosure.

Referring to FIG. 2b, in another aspect, the thermal insulation member 203 can at least include a first thermal insulation member 203a adjacent to the support plate 201 and a second thermal insulation member 203b adjacent to the support shaft 202. In other words, the first thermal insulation member 203a is arranged above the second thermal insulation member 203b, and at least one cavity S is provided as the thermal insulation region. Optionally, the first thermal insulation member 203a and the second thermal insulation member 203b can be made of different materials. For example, a thermal conductivity of the first thermal insulation member 203a can be greater than a thermal conductivity of the second thermal insulation member 203b, such that the heat from the support plate 201 is readily removed by the thermal insulation member 203 while not being readily conducted to the support shaft 202.

Further, each of the first thermal insulation member 203a and the second thermal insulation member 203b can be made of a highly thermally conductive material having a thermal conductivity (coefficient of thermal conductivity) of greater than 10 W/m·K, for example, a thermal conductivity of 34 W/m·K, 35 W/m·K, 60 W/m·K, 70 W/m·K, 80 W/m·K, 237 W/m·K, 401 W/m·K, etc. For example, each of the first thermal insulation member 203a and the second thermal insulation member 203b can be made of ceramic, iron, copper, etc., which is highly thermally conductive. However, the above examples are merely one of the possible embodiments and are not intended to limit the present disclosure. In one embodiment, the first thermal insulation member 203a and the second thermal insulation member 203b can have different thermal conductivities. For example, the first thermal insulation member 203a can have the thermal conductivity of 35 W/m·K and the second thermal insulation member 203b can have the thermal conductivity of 80 W/m·K. In another aspect, each of the first thermal insulation member 203a and the second thermal insulation member 203b can be made of a thermal insulation material having a thermal conductivity (coefficient of thermal conductivity) of less than 2 W/m·K, such as glass (having a thermal conductivity of 1.4 W/m·K) and low thermally conductive ceramic (having a thermal conductivity of less than 2 W/m·K), but the present disclosure is not limited thereto.

### Third Embodiment

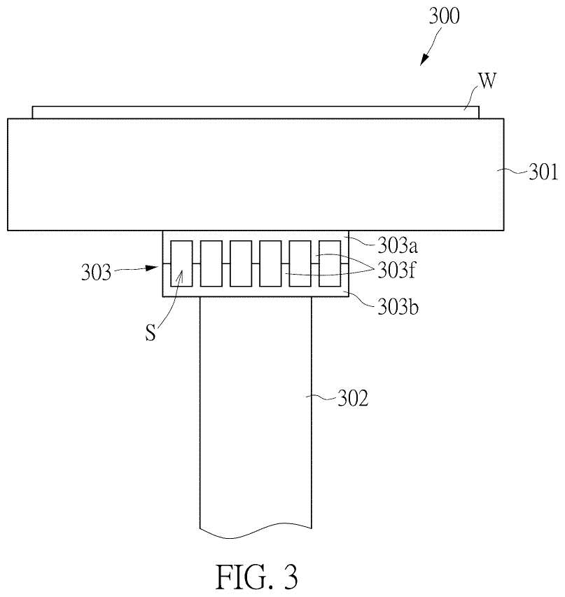

Reference is made to FIG. 3, in which a schematic side view of a chuck 300 according to a third embodiment of the present disclosure is shown, in another embodiment of the present disclosure, the chuck 300 can include a support plate 301, a support shaft 302, and a thermal insulation member 303. The similarities between the third embodiment and the first embodiment will not be reiterated herein. In the present embodiment, the thermal insulation member 303 can include a plurality of fins 303f, so that a plurality of cavities S are provided in the thermal insulation member 303 as thermal insulation regions.

Similar to the above embodiments, the cavities S can be directly used as flow spaces for the CDA or the coolant, or fluid channels can be provided in the cavities S to allow the CDA or the coolant to flow therein. In other words, as shown in FIG. 3, the CDA or the coolant can flow between the plurality of fins 303f to remove the heat from the cavities S.

Further, the thermal insulation member 303 can at least include a first thermal insulation member 303a adjacent to the support plate 301 and a second thermal insulation member 303b adjacent to the support shaft 302. In other words, the first thermal insulation member 303a is arranged above the second thermal insulation member 303b, and at least one cavity S is provided as the thermal insulation region. Optionally, the first thermal insulation member 303a and the second thermal insulation member 303b can be made of different materials. For example, a thermal conductivity of the first thermal insulation member 303a can be greater than a thermal conductivity of the second thermal insulation member 303b, such that the heat from the support plate 301 is readily removed by the thermal insulation member 303 while not being readily conducted to the support shaft 302.

### Fourth Embodiment

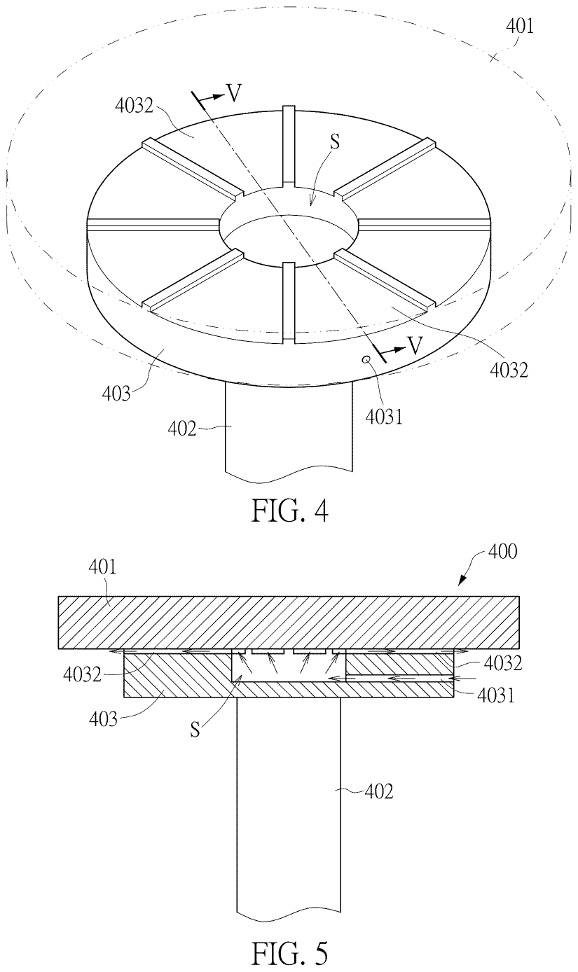

Reference is made to FIG. 4 and FIG. 5, in which a perspective view of a chuck 400 according to a fourth embodiment of the present disclosure is shown in FIG. 4, and a schematic side view of the chuck 400 according to the fourth embodiment of the present disclosure is shown in FIG. 5, in another embodiment of the present disclosure, the chuck 400 can include a support plate 401, a support shaft 402, and a thermal insulation member 403. The thermal insulation member 403 can be used to avoid direct contact between the support plate 401 and the support shaft 402, thereby avoiding the heat from the support plate 401 from being transmitted to the support shaft 402. Further, the thermal insulation member 403 can have a cavity S that serves as a flow space for the CDA or the coolant. In addition, the thermal insulation member 403 further has a fluid inlet 4031 and a fluid outlet 4032 to direct the CDA or the coolant respectively into and out of the cavity S, thereby facilitating the flow of the CDA or the coolant.

In one embodiment of the present disclosure, the thermal insulation member 403 has one fluid inlet 4031 and at least two fluid outlets 4032. In addition, the fluid inlet 4031 and the fluid outlet 4032 can be at different levels. For example, the fluid inlet 4031 can be arranged on a body of the thermal insulation member 403, and the fluid outlet 4032 can be arranged adjacent to the support plate 401. In other words, the fluid inlet 4031 is arranged below the fluid outlet 4032. That is, the CDA or the coolant is not adjacent to the support plate 401 before entering the cavity S, so that the CDA or the coolant can be maintained at a lower temperature. When the CDA or the coolant flows to the fluid outlet 4032, the CDA or the coolant can be in direct contact with the support plate 401, which can increase the heat dissipation efficiency of taking the heat away from the support plate 401.

Specifically, when the CDA or the coolant is introduced into the cavity S via the fluid inlet 4031 with a first temperature, the CDA or the coolant is discharged from the cavity S via the fluid outlet 4032 with a second temperature, and the second temperature is greater than the first temperature, indicating that the CDA or the coolant is effective in taking the heat from the cavity S.

### Fifth Embodiment

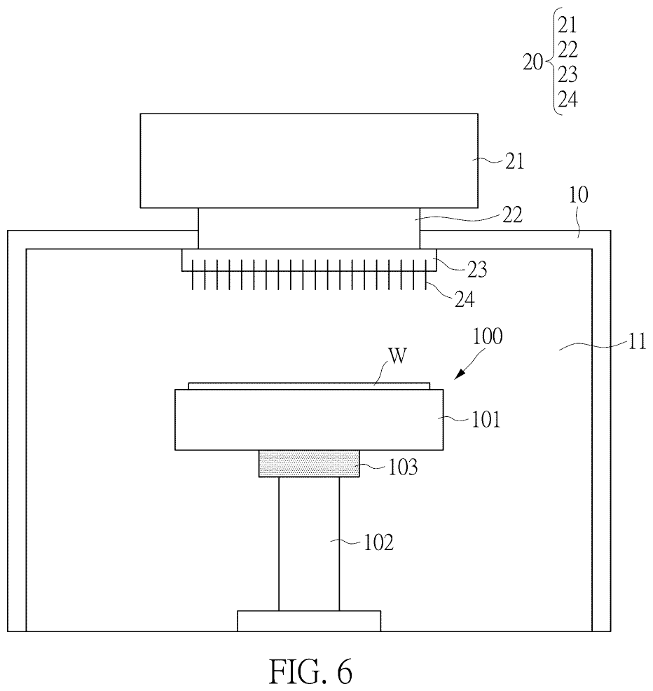

Further, the chuck of the present disclosure can be applied in a wafer test device. Taking the chuck 100 according to the first embodiment of the present disclosure as an example, as shown in FIG. 6, the wafer test device can include a housing 10, a test unit 20, and the chuck 100. A space surrounded by the housing 10 can be used as a test chamber 11 for testing the wafer. The test unit 20 is disposed on a top of the housing 10 and located in the test chamber 11.

The test unit 20 can include a test head 21, an interface 22, a probe card 23, and probes 24. The test head 21 is used to apply an electrical signal when the wafer W is in contact with the probe card 23, and to determine a state of the wafer W through a response of the wafer W to the electrical signal that is input. The interface 22 is used to provide a space for electrical connection between the probe card 23 and the test head 21. The probe card 23 includes multiple probes 24.

When the wafer testing is conducted, a transfer device can be used to place the wafer W on the support plate, and the support shaft is used to adjust a position of the wafer W correspondingly in the vertical direction and the horizontal direction to perform alignment of the probe card 23 with the wafer W. Subsequentially, the wafer W is brought into contact with the multiple probes 24, and then the test head 21 is used to apply the electrical signal to test the wafer W.

### BENEFICIAL EFFECTS OF THE EMBODIMENTS

In conclusion, one of the beneficial effects of the present disclosure is that in the chuck provided by the present disclosure, by virtue of “the support plate for holding the wafer to be processed, the support shaft being disposed below the support plate for supporting the support plate” and “the thermal insulation member being disposed at a connection between the support plate and the support shaft,” the heat transmission from the support plate to the support shaft can be prevented, while the heat applied to the wafer W is not removed. Further, the thermal insulation member of the present disclosure is made of a highly thermally conductive material, so that the heat of the support plate can be transmitted upward to the wafer but not downward to the support shaft. Therefore, the support plate of the present disclosure does not need to be provided with additional heat-resistant layers or insulation layers, thereby reducing process costs.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chuck, comprising:
a support plate for holding a test wafer;
a support shaft disposed below the support plate for supporting the support plate;
a thermal insulation member disposed between the support plate and the support shaft and including:
at least one first thermal insulation member disposed below the support plate and adjacent to the support plate;
at least one second thermal insulation member disposed below the at least one first thermal insulation member and adjacent to the support shaft; and
at least one cavity, at least one fluid channel being provided in the at least one cavity, and the at least one cavity being surrounded by the at least one first thermal insulation member and the at least one second thermal insulation member;
wherein a thermal conductivity of the at least one first thermal insulation member is greater than a thermal conductivity of the at least one second thermal insulation member;
wherein at least one thermal insulation region is provided in the thermal insulation member, and the at least one thermal insulation region is arranged between the support plate and the support shaft;
wherein at least a part of the support shaft supports the support plate through the thermal insulation member.

2. The chuck according to claim 1, wherein the thermal insulation member has:
at least one fluid inlet spatially communicated with the at least one cavity to direct a cooling fluid into the at least one cavity; and
at least one fluid outlet spatially communicated with the at least one cavity to direct the cooling fluid out of the at least one cavity.

3. The chuck according to claim 2, wherein the at least one fluid inlet and the at least one fluid outlet are at the same level.

4. The chuck according to claim 1, wherein the at least one first thermal insulation member includes a plurality of fins.

5. A chuck, comprising:
a support plate for holding a test wafer;
a support shaft disposed below the support plate for supporting the support plate;
a thermal insulation member disposed between the support plate and the support shaft and including:
a first thermal insulation member;
a second thermal insulation member, wherein a thermal conductivity of the first thermal insulation member is equal to a thermal conductivity of the second thermal insulation member; and
at least one cavity, at least one fluid channel being provided in the at least one cavity, and the at least one cavity being surrounded by the first thermal insulation member and the second thermal insulation member;
wherein at least one thermal insulation region is provided in the thermal insulation member, and the at least one thermal insulation region is arranged between the support plate and the support shaft.

6. The chuck according to claim 5, wherein the thermal insulation member has:
at least one fluid inlet spatially communicated with the at least one cavity to direct a cooling fluid into the at least one cavity; and
a plurality of fluid outlets spatially communicated with the at least one cavity to direct the cooling fluid out of the at least one cavity;
wherein the at least one fluid inlet is arranged below the plurality of fluid outlets.

7. The chuck according to claim 5, wherein a width of the thermal insulation member is greater than or equal to a width of the support shaft.

8. The chuck according to claim 5, wherein the thermal insulation member includes a plurality of fins.

9. The chuck according to claim 5, wherein the first thermal insulation member and the second thermal insulation member are made of the same material.

10. The chuck according to claim 5, wherein the first thermal insulation member and the second thermal insulation member are integrally formed.
